(19) United States
(12) Patent Application Publication
(10) Pub. No.: US 2026/0308751 A1
(43) Pub. Date: Oct. 8, 2026

(54) Computer Implemented Method for Predicting a Level of Quality of a Vacuum into a Vacuum Chamber of a Coating Machine, and Corresponding Device

(71) Applicant: Essilor International, Charenton-le-Pont (FR)

(72) Inventors: Francis HENKY, Charenton-le-Pont (FR); Takfarinas NAIT LARBI, Charenton-le-Pont (FR)

(21) Appl. No.: 19/485,522

(22) PCT Filed: May 22, 2024
(86) PCT No.: PCT/EP2024/064051

§ 371 Date: Nov. 18, 2025

(30) Foreign Application Priority Data
May 24, 2023 (EP) 23305827.0

(51) Int. Cl. C23C 14/52; C23C 14/04; C23C 14/30; C23C 14/54; G02B 1/115; G06N 20/20

(52) U.S. Cl. CPC C23C 14/52; C23C 14/042; C23C 14/30; C23C 14/54; G02B 1/115; G06N 20/20

(57) ABSTRACT

The invention relates to a computer implemented method for predicting a level of quality of a vacuum into a vacuum chamber (2) of a coating machine (1) suitable for coating optic elements (8). According to the invention, this method comprises steps of: —acquiring at least one technical feature of the coating machine during coating processes of optic elements, and —predicting said level of quality from the at least one measured technical feature by means of a processing unit that registers a machine learning model, said at least one technical feature being an input of said machine learning model and said level of quality being an output of said machine learning model.

### TECHNICAL FIELD OF THE INVENTION

The invention generally concerns devices and methods relating to deposition of coatings onto substrates, under vacuum.

It more particularly relates to a computer implemented method for predicting a level of quality of a vacuum into a vacuum chamber of a coating machine suitable for coating optic elements such as lens substrates.

### BACKGROUND INFORMATION AND PRIOR ART

Multiple types of functional coatings can be applied to an optical substrate such as an eyeglass lens substrate.

For example, it is common for a pair of eyeglass lenses to have three or four different coatings, such as an anti-reflective coating, an anti-scratch coating, an anti-static coating, and a hydrophobic coating.

The anti-reflective coating is a thin multi-layer coating that reduces light reflecting from the lenses.

In the manufacturing of eyeglass lenses, a single machine can apply the anti-reflective coating.

For instance, document EP3268507 discloses a vapor deposition machine that can be used to apply an anti-reflective coating and a hydrophobic coating to a plurality of eyeglass lens substrates.

Such a machine comprises a pumping system and a vacuum chamber having a floor, a substrate holder disposed above the floor and configured to receive several substrates, and distinct evaporators disposed in the vacuum chamber below the substrate holder and configured to evaporate coatings. A gauge is used to determine the pressure in the chamber and to control the pumping system accordingly.

To ensure a satisfying quality of the coatings, the vacuum in the chamber has to be maintained at a very low pressure.

Therefore, it is essential to avoid any leaks in the chamber, these leaks coming from holes or cracks in the frame of the chamber or in the joints, or from dirt inside the chamber (water . . . ). It is also essential to determine if the gauge is working properly.

Consequently, leak rate and gauge tests are regularly performed to check whether the vacuum quality is correct or not.

The leak test consists in measuring a pressure increase during a predetermined time period thanks to the gauge.

To obtain usable results, some conditions have to be fulfilled during the test. For instance, the vacuum gauge must be calibrated, the vacuum chamber must be clean, the vacuum chamber degassing must be properly done, and the pumping system must work correctly.

The result of this test has to be fewer than a predetermined threshold. Else, a warning is issued.

The purpose of the gauge test is to detect a gauge drift or wrong measurement. To detect such a problem, the test consists in injecting a predetermined and continuous flow of gas in the vacuum chamber, waiting for a few minutes for stabilization, measuring the pressure in the chamber, and verifying whether this pressure is in a predefined range of pressure or not. If not, a warning is issued.

In summary, both tests make it possible to determine a level of quality of a vacuum in the chamber.

These leak and gauge tests must be carried out very often (for instance every week), even if they last a long time (from 5 to 13 hours). It is indeed the only known solution to check that the machine is in good and stable condition, to guarantee the quality of the coatings, to keep constant process conditions, to keep chamber cleanliness, leaks and contamination under control . . .

### SUMMARY OF THE INVENTION

In this context, the present invention provides a solution to reduce the time required to implement these tests.

The invention more precisely concerns a computer implemented method for predicting a level of quality of a vacuum into a vacuum chamber of a coating machine suitable for coating optic elements. According to the invention, this method comprises steps of:
S1) acquiring at least a value of at least one technical feature of the coating machine during a coating process of the optic elements, and
S2) predicting said level of quality from the at least one acquired value by means of a processing unit that registers a machine learning model, said at least one technical feature value being an input of said machine learning model and said level of quality being an output of said machine learning model.

In other words, the invention consists in using a machine learning model suitable to observe the values of working parameters of the coating machine and to determine whether this machine suffers from a problem or not.

The main advantage of this invention is to reduce the time required to check the state of health of the machine, so as to increase productivity. It is indeed no longer necessary to carry out leak and gauge tests as regularly as before. It is for example possible to space out these tests, or to implement these tests only if the learning model detects a problem.

Other preferred features of the invention are the following ones:
said at least one technical feature value is measured during the coating process of the optic elements,
said at least one technical feature value is measured on the coating machine;
said at least one technical feature value varies during the coating process of the optic elements,
said at least one technical feature value is different from the coating process of a batch of optic elements to the coating process of another batch of optic elements, said batches being processed at distinct times,-said at least one technical feature value is determined as a function of the variation of said technical feature during at least a part of said coating process;
said technical feature value is determined as a function of the variation of said technical feature during several coating processes of distinct optic elements;
said at least one technical feature comprises a pressure in said vacuum chamber after having at least partially coated the optic elements, and/or a pressure in said vacuum chamber when a gas is introduced into said vacuum chamber, and/or a pumping time to reach a predetermined pressure in said vacuum chamber, and/or, if said optic elements are coated by a ion gun, a ion gun usage time, and/or a number of recoveries of said coating process;
during the coating of the optical elements, the pressure in said vacuum chamber is comprised between 10⁻³ and 10⁻⁶ Pa;
during the coating of the optical elements, the temperature inside said vacuum chamber is equal to the temperature outside said vacuum chamber, within 20 °C;
said output only depends on said input(s);
said level of quality comprises a binary data that is different depending on whether the quality of the vacuum is acceptable or not for coating the optical elements;
the level of quality is a value or a category based on at least one defined threshold;
the level of quality is at least partially defined by a leak rate of a vacuum chamber of said coating machine (1) and the machine learning model is a leak rate machine learning model;
the level of quality is at least partially defined by a pressure of a specific gas in said vacuum chamber and the machine learning model is a gauge machine learning model;
said machine learning model is of the classification kind;
said machine learning model is based on a random forest method.

At this step, we can explain that the ion gun generates dirt in the vacuum chamber, which is likely to generate vacuum failures and reduce the lifespan of the machine. Thus, it is judged that the usage time of this ion gun constitutes a good indicator of the vacuum quality.

The invention also relates to a process for setting up a processing unit suitable for predicting a level of quality of a vacuum in a vacuum chamber of a coating machine suitable for coating optic elements, comprising steps of:
making a database associating in input values of at least one technical feature of the coating machine with in output levels of quality,
a step of training a machine learning model, said machine learning model receiving said database as training data, and
registering the trained machine learning model in the processing unit.

Said database is made with data (the inputs and outputs) that are measured during previous operations of coating batches of optic elements.

Other preferred features of the invention are the following ones:
the values in said database are measured on distinct coating machines located in distinct countries, and said trained machine learning model is usable on coating machines located in at least two distinct countries;
said database is divided in a training set on the basis of which said machine learning model is trained, and a test set on the basis of which said machine learning model is assessed;
to assess said machine learning model, the technical feature values recorded in the test set are used as input for the trained machine learning model and the obtained output are compared with the corresponding levels of quality recorded in the test set.
said machine learning model is assessed if a parameter quantifying the rate of false positives is greater than a predetermined threshold, a false positive corresponding to a situation where a low level of quality is not detected by the machine learning model.

The invention also relates to a processing unit programmed for predicting a level of quality of a vacuum into a vacuum chamber of a coating machine suitable for coating optic elements, said processing unit comprising an input interface for acquiring at least a value of at least one technical feature of the coating machine during a coating process of the optic elements, and a predicting unit for predicting said level of quality from the at least one acquired value by means of a machine learning model, said at least one technical feature value being an input of said machine learning model and said level of quality being an output of said machine learning model.

In a preferred embodiment, said processing unit is suitable for performing the above process.

The invention also relates to a vacuum coating machine suitable for coating optic elements, comprising:
a vacuum chamber housing said optic elements,
a pumping device to evacuate any gas from said vacuum chamber,
acquiring means suitable to acquire at least a value of at least one technical feature of the coating machine during a coating process of said optic elements,
the above processing unit.

In a preferred embodiment, the vacuum coating machine comprises a reporting unit connected to said processing unit and suitable to communicate the predicted level to an individual, said reporting unit being preferably a loudspeaker generating an audible signal to communicate the predicted level of quality or a screen displaying a visual representation of the predicted level of quality.

### DETAILED DESCRIPTION OF EXAMPLE(S)

The following description with reference to the accompanying drawings, given by way of non-limiting example makes it clear what the invention consists in and how it can be reduced to practice.

In the accompanying drawings:

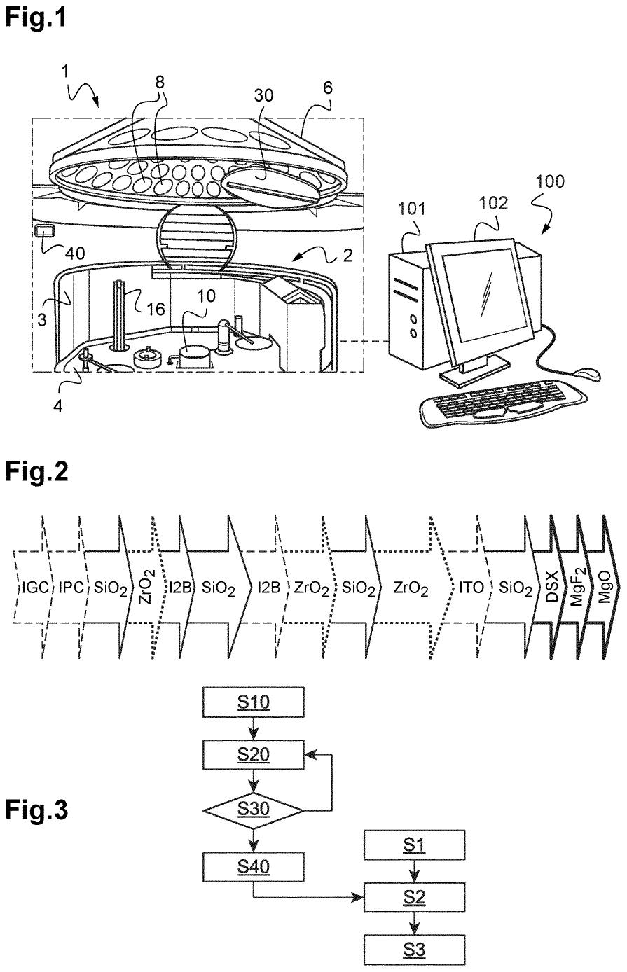

FIG. 1 is a schematic perspective view of a vacuum chamber of an embodiment of a vapor deposition apparatus according to the invention,

FIG. 2 illustrates a diagram of a process of depositing coating layers on a lens substrate into the vacuum chamber of FIG. 1,

FIG. 3 is a diagram of a method for predicting a level of quality of a vacuum into the vacuum chamber of FIG. 1.

FIG. 1 shows an interior view of a vapor deposition apparatus 1 suitable for coating one or more substrates 8 so as to form ophthalmic lenses.

The vapor deposition apparatus 1 is configured to apply distinct functional coatings onto several substrates 8.

To this end, this vapor deposition apparatus 1 comprises a pumping system, a frame defining a vacuum chamber 2 to which said pumping system is connected, a substrate holder 6 disposed in the vacuum chamber 2 (here in the top of this chamber), a chamber floor 4 opposite to the substrate holder 6, and at least one evaporator.

The substrate holder 6 is configured to receive and hold substrates 8. In the illustrated embodiment, eyeglass lenses are the substrates to be coated.

In FIG. 1, there are two evaporators 10, 16 disposed in the vacuum chamber 2 below the substrate holder 6.

In the shown embodiment, the first evaporator 10 is configured for electron beam evaporation, ion-assisted evaporation, or ion beam sputtering. It is configured to apply one or more layers of an anti-reflective coating. For example, first evaporator 10 can be configured to apply one or more metal oxide layers by electron beam evaporation. It can also be configured to apply an anti-static layer, an anti-scratch layer, a mirror layer, a tinted/colored layer, and/or a hardening layer.

The second evaporator 16 is configured to evaporate a hydrophobic material so that the hydrophobic material forms a hydrophobic coating (e.g., an anti-The pumping system, not shown in FIG. 1, may comprise a single pump suitable to extract any gas from the vacuum chamber 2. But in a preferred embodiment, it comprises two kind of pumps, preliminary pumps suitable to be activated for reducing the pressure in the chamber from the atmospheric pressure to an intermediate pressure, and secondary pumps suitable to be activated for reducing the pressure in the chamber from the intermediate pressure to the target pressure. We can note that both kinds of pumps can be activated together when the pressure is lower than the intermediate pressure.

The target pressure is comprised between 10⁻³ and 10⁻⁶ Pascal.

The temperature inside the vacuum chamber remains equal to the temperature outside said vacuum chamber, within 20 °C, whatever the pressure.

In some embodiments, the apparatus 1 can further comprise means for introducing a flow of a specific gas (here oxygen) into the vacuum chamber. These means, combined with the pumping system, can be used to maintain the pressure in the chamber at a very accurate value.

It can also further comprise a vapor distribution mask 30, configured to block vapor from depositing on some of the substrates 8 when these substrates 8 are located behind the mask 30.

FIG. 1 also shows a control unit 100 that comprises a processing unit 101 and a Man Machine Interface.

The processing unit 101 comprises at least one CPU or controller (also called “predicting unit”), or any combination thereof. It also comprises a memory and various input and output interfaces.

Thanks to its input interfaces, the processing unit 101 is suitable for receiving data from sensors.

Thanks to its output interfaces, the processing unit is suitable for controlling the Man Machine Interface and for communicating with a remote server (in the cloud).

Here, this Man Machine Interface comprises a display screen 102 and a keyboard. It can also include loudspeakers.

Thanks to its memory, the processing unit 101 stores a computer application, consisting of computer programs comprising instructions, the execution of which by the processor enables the processing unit to implement the process Said sensors are designed to measure technical features of the coating machine 1.

For instance, a pressure gauge 40 (a manometer) is suitable to measure a pressure in the vacuum chamber 2. This gauge 40 is designed to accurately measure small pressures.

This coating apparatus 1 will not be described in more details since such a machine is well known from the art (it is for instance sold under the reference Satisloh 1200-DLX-2).

FIG. 2 shows an example of a cycle used to coat the substrates 8 by means of the vapor deposition apparatus 1 of FIG. 1.

This cycle comprises the following steps:
ion gun conditioning (IGC) and ion pre-clearing (IPC) that consists in bombarding the substrates surfaces with ions to clean them,
depositing a first layer of SiO₂ on the substrates 8,
depositing a layer of ZrO₂ on the substrates 8,
ion interlayers bombardment (I2B) to provide the layer with a good adhesion surface,
depositing a second layer of SiO₂ on the substrates 8 in order to improve the abrasion resistance,
another ion interlayers bombardment,
depositing a layer of ZrO₂ on the substrates 8,
depositing a third layer of SiO₂ on the substrates 8,
depositing a layer of ZrO₂ on the substrates 8,
depositing a layer of SnO₂ (ITO) on the substrates 8 in order to form an antistatic layer,
depositing a last layer of SiO₂ on the substrates 8,
depositing a topcoat (DSX) having anti-smudge, hydrophobic and oleophobic functions,
depositing a layer of MgF₂ and then a layer of MgO (BlueOverLayer) on the substrates 8 to help a pad adhesion, such pad being used to catch the lens in order to put it in a machining device.

During all the cycle, the pumping system is activated. In practice, this cycle comprises a preliminary step of vacuuming the chamber 2, and a last step of increasing the pressure in the chamber to unload the substrates 8.

Here it can be noted that this cycle is only an example. Other cycles can be used. Some of them can for instance only comprise some of the above steps.

To coat a lens accurately and efficiently, the coating machine 1 must be in perfect working order and clean. The invention therefore consists in verifying that this is indeed the case.

To this end, during such a cycle, the processing unit determines, thanks to the gauge 40, the value of the pressure in the vacuum chamber 2.

More precisely, thanks to sensors, it determines the values (and their variation) of several features (Step S1 in FIG. 3).

These features are chosen so as to be already available (because measured) on a wide range of coating machines. Consequently, the implementation of the invention on these coating machines does not require any modification on the hardware of these machines.

Here, these technical features comprise at least two of the following data (here they comprise all the following data).

The first technical feature is the pressure in the vacuum chamber during said coating cycle.

This technical feature relates more precisely to the value of the pressure in this chamber during the step of depositing the last layer of SiO₂. This feature gives an information relating to the vacuum chamber condition (leak) and the gauge condition.

In practice, the determined value is the mean or the standard deviation or the maximum of the pressure during this step.

The second technical feature is a pumping time before the coating of the substrates 8.

In practice, the determined value is the time necessary for decreasing the pressure in the vacuum chamber from the atmospheric pressure to the target pressure.

This technical feature reflects the chamber working conditions.

In a variant, this second technical feature can be characterized by two values, a first pumping time (to reach the intermediate pressure) and a second pumping time (to reach the target pressure).

The third technical feature is the pressure in the vacuum chamber when gas is introduced in the chamber by the introducing means.

This technical feature gives an information relating to the gauge condition. Indeed, if the measured pressure does not correspond to the flow of introduced gas, it is likely that the gauge suffers from a problem.

In practice, the determined value is the mean or the standard deviation or the maximum of the pressure.

The fourth technical feature is the ion gun usage time during the entire cycle.

This technical feature reflects the kind of steps performed during the cycle, and gives information on its complexity and its impact on the chamber cleanliness. In other words, the higher this time, the greater the risk of leakage.

The fifth technical feature is the number of recoveries, which corresponds to the number of times the cycle was interrupted.

This technical feature reflects the machine and the gauge working conditions.

In practice, at the end of each cycle, the coating machine 1 generates a logfile, that is to say a file storing parameters of the machine, in particular the values of the five aforementioned technical features.

This logfile comprises more than the values of the above technical features. It also comprises many other values, some of them being able to be used since they reflect the machine and the gauge working conditions.

These technical features comprise here:
an identifier of the used coating machine 1,
an identifier of the laboratory in which this machine is located,
a using time of the machine (to perform the entire cycle),
a pumping gap, corresponding to the difference between the pumping time by means of the primary pumps and the pumping time by means of the secondary pumps,
a value relating to a Meissner temperature (this temperature being the one of a device located in the chamber 2 and that is at a low temperature, lying between −120 and −130 °C, making it possible to capture water as a pump), this value being for instance the mean or standard deviation or the maximum of this temperature,
the time elapsed between the beginning of the cycle and the first step of
an opening time of a cover of the ion gun (considering that the material to be evaporated is located into a crucible having a cover that is opened only after the material has reached a pre-set temperature),
a quartz frequency value (said quartz being used to measure the thickness of the coating), this value being for instance the mean or standard deviation or the maximum or the minimum of this frequency,
a thickness of the coating,
a number of alarms triggered during the cycle,
a total number of cycles performed by the machine,
a number of special cycles performed by the machine (a special cycle being a cycle during which the thickest layer of SiO₂ is deposited on the substrate, this layer being the one that improves anti-scratch properties, here the second layer of SiO₂),
a percentage of special cycles.

In the following, a logfile will be considered as a file comprising all the above values.

This single logfile may be used to predict the level of quality of the vacuum made in the chamber 2.

But in a preferred embodiment, at least two logfiles are used, making it possible to determine the variations of said values from a cycle to another.

Here, the logfiles of an entire week are used to predict this level of quality. More precisely, these logfiles are combined to predict this level of quality. To this end, all the values taken during the last week by each technical feature are combined in a final value. This final value can be the sum of the corresponding values, the maximum or minimum of them, the mean, the standard deviation . . . .

Then, on the basis of the final values of the technical features, the processing unit 101 predicts a level of quality of the vacuum made in the chamber 2 (step S2 in FIG. 3).

The term quality designates here to what extent the coating machine is capable of placing the chamber 2 under a precise predetermined pressure.

In other words, here, this level of quality is defined by two distinct parameters:
a leak rate linked to the cleanliness and the tightness of the vacuum chamber 2, and
a pressure value in this vacuum chamber 2 linked to the reliability of the gauge 40.

These leak rate and pressure value are those usually measured during standard tests made on coating machines (as described above).

To determine the leak rate and the pressure value, the processing unit 101 uses at least one machine learning model stored in its memory.

Here, it uses two distinct models, named leak rate machine learning model and gauge machine learning model.

Each machine learning model is configured so that these level of quality parameters can be determined on the only basis of the above final values (that is to say on the basis of the last logfiles). Consequently, these final values form the inputs of both machine learning models and said level of quality parameters are the outputs of these machine learning models.

Each level of quality parameter can be expressed by a value (for instance the leak rate and the pressure value). But here, these parameters are rather expressed as a category. Two categories for each parameter are here used: they are for instance labelled OK and not-OK.

The category is deduced from the comparison of the above value (the leak rate or the pressure value) with a pre-set threshold.

In other words, if the leak rate is above a pre-set threshold (for instance 6*10⁻³ Pa. Litres/second), the level of quality relating to the leak rate is considered not-OK. Else, it is considered OK. And if the pressure value differs from a pre-set threshold (for instance being out of the range lying from 8*10⁻³ to 1.1*10⁻² Pa), the level of quality relating to the reliability of the gauge 40 is considered not-OK. Else, it is considered OK.

Here, the machine learning models are based on a random forest method. Such a method is well known and will not be described here.

In a variant, they may be based on other kinds of algorithm (for instance on neural networks).

As it will be explained in more details hereunder, the machine learning models are used to determine, on the basis of the logfiles of the previous week, the categories of leak rate and gauge reliability.

But before, it will be explained how these models are trained.

This training is performed thanks to data that are preferably stored in a database.

To generate this database, the following process, also shown in FIG. 3, is implemented.

The first step S10 consists in building a usable database.

This database comprises several fields (or columns), the firsts of which are respectively associated with the finale values and the last of which correspond to the values (OK or not-OK) of the categories of leak rate and gauge reliability.

This database comprises registers (or lines) each corresponding to a single week of use of a coating machine. The values stored in each register are determined on the basis of:
logfiles generated during this week and
results of standard leak and gauge tests carried out at the end of the week.

A standard leak test consists in measuring a pressure increase during a predetermined time period thanks to the gauge 40. The results are expressed in Pa·l/s (Pa·liters/second). If the result of this test is fewer than a predetermined threshold, the value of the category of leak rate is labelled OK. Else, it is labelled Not-OK.

The standard gauge test consists in injecting a flow of oxygen in the vacuum chamber during a few minutes, measuring (not at the beginning of the injection but at least one minute later) the pressure in the chamber 2, and verifying if this pressure is in a predefined range of pressure. If so, the value of the category of gauge reliability is labelled OK. Else, it is labelled Not-OK.

These standard tests are regularly performed (here at the end of each week), so that it is possible to create, after each couple of tests, a new register in the database filled with this information.

The register created at the end of a week thus comprises the final values calculated on the basis of the logfiles elaborated during the week, and the label of the categories of leak rate and gauge reliability determined by means of the standard tests.

When the database comprises enough registers, for instance at least 500, it is used to train the machine learning models.

In a preferred embodiment, several coating machines are used to create the registers, these machines being located in various countries. Consequently, the machine learning models will be trained with data coming from distinct environments, so that they will be usable anywhere in the world.

In a variant, a couple of machine learning models can be trained and develop for each kind of environment.

For training (step S20) and validating (step S30) the machine learning models, the obtained database is divided in two parts, the first part of the registers forming a training set to train the machine learning models, and the other part forming a test set for determining whether the trained machine learning models produce good results or not.

The first part comprises for instance 70% of the registers when the second part comprises 30% of them.

The data comprised in the first part of the registers (training set), indicating not only the final values but also the corresponding categories of leak rate and gauge reliability, are used to train the machine learning models, for instance by means of a bagging method.

Once the machine learning models trained and set-up, the final values stored in the second part of the registers (the test set) are used as input of the trained machine learning models. Consequently, each register makes it possible to determine, on the basis of the final values, the corresponding categories of leak rate and gauge reliability.

These determined categories are then respectively compared with those stored in the second part of the registers. More precisely, the categories stored in each register of the test set are compared to the categories determined by the machine learning models on the basis of the final values stored in this register.

The aim of this comparison is to determine if the result of the models are equals or not with the results of the performed standard tests.

To this end, at least one efficacy parameter is calculated, this parameter having for instance a value equal to 100% when the determined and stored categories have same values, and equal to 0% when none of the determined and stored categories have same values.

If this efficacy parameter is above a pre-set threshold, the trained machine learning model is considered usable. Then, it is recorded in the memory of the processing unit (which can then use it to determine each week the level of quality of the vacuum in the coating machine 1).

Else, it has to be trained again. To this end, the database can be split into another couple of training and test sets, or the database can be supplemented (by performing other standard tests to create new registers).

Many efficacy parameters may be used, for instance an accuracy, a precision, a recall and/or a F1-score.

The accuracy is equal to the ratio of the number of correct predictions and the total number of predictions.

The precision is equal to the ratio of the number of true-positive predictions and the total number of true-positive and false-positive predictions.

The recall is equal to the ratio of the number of true-positive predictions and the total number of true-positive and false-negative predictions.

The F1-score is equal to twice the product of the precision and the recall, divided by the sum of precision and recall.

Here, the efficacy parameter used to assess if the models are well-trained is the precision, the recall and/or the F1-score since these parameters quantify the rate of false-positives (a false positive corresponding to a situation where an insufficient level of quality is not detected by the machine learning models).

When the machine learning models are well trained and validated, they are registered in the memory of the processing unit of the coating machine 1 (step S40).

And during every further cycle of the kind shown in FIG. 2, the processing unit 101 will be able to continue to measure the technical features values and to determine new logfiles.

Then, when an individual want to know whether the coating machine 1 works well or not, the processing unit can use the machine learning models and the logfiles of the previous week to determine the category of leak rate and the category of gauge reliability.

In other words, it is no longer necessary to carry out the standard tests insofar as the machine learning models will make it possible to determine if one of these categories takes the value not-OK.

Of course, it could be possible to carry out standard tests, at a lower frequency however, to check that the results obtained by the machine learning model are correct and/or to complete the database so as to improve the machine learning models (to make them more reliable).

Anyway, as long as the categories are in OK status, no repair is undertaken and the machine 1 can be used without problems.

On the other hand, as soon as one of the categories is in the not-OK status, a message is sent to an operator via the Man-Machine interface (Step S3). This message consists in warning an individual that a problem may have been detected. This message can take the form of an audible signal or a message displayed on the screen.

Upon receipt of this signal, provision can be made to check that the chamber is properly closed and clean and, if this is the case, to carry out a standard test to confirm the results given by the machine learning model, or to call a repairer. A variant of this embodiment can be considered.

For instance, the statuses of the two categories can be combined into a single global status OK or not-OK (this global status being a binary data equal to “OK” or “1” only if the statuses of the two categories are OK).

The processing unit 101 can then emit a signal containing this global status, intended for users of the machine.

In this case, it can generate at regular intervals a file containing this global status.

Preferably, the global status includes an indicator of the level of failure, allowing the user to know if he must carry out a slight or a major maintenance on the machine.

1. Computer implemented method for predicting a level of quality of a vacuum into a vacuum chamber of a coating machine suitable for coating optic elements comprising steps of:
S1) acquiring at least a value of at least one technical feature of the coating machine during a coating process of the optic elements, and
S2) predicting said level of quality from the at least one acquired value by means of a processing unit comprising a machine learning model, said at least one technical feature value being an input of said machine learning model and said level of quality being an output of said machine learning model.

2. Computer implemented method according to claim 1, wherein said at least one technical feature value is determined as a function of the variation of said technical feature during at least a part of said coating process.

3. Computer implemented method according to claim 1, wherein said technical feature value is determined as a function of the variation of said technical feature during several coating processes of distinct optic elements

4. Computer implemented method according to claim 1, wherein said at least one technical feature comprises:
a pressure in said vacuum chamber after having at least partially coated the optic elements,
a pressure in said vacuum chamber when a gas is introduced into said vacuum chamber,
a pumping time to reach a predetermined pressure in said vacuum chamber,
if said optic elements are coated by a ion gun, a ion gun usage time,
a number of recoveries of said coating process.

5. Computer implemented method according to claim 1, wherein the level of quality is at least partially defined by a leak rate of a vacuum chamber of said coating machine and the machine learning model is a leak rate machine learning model.

6. Computer implemented method according to claim 1, wherein the level of quality is at least partially defined by a pressure of a specific gas in said vacuum chamber and the machine learning model is a gauge machine learning model.

7. Computer implemented method according to claim 1, wherein said machine learning model is based on a random forest method.

8. Process for setting up a processing unit suitable for predicting a level of quality of a vacuum in a vacuum chamber of a coating machine suitable for coating optic elements comprising steps of:
making a database associating in input values of at least one technical feature of the coating machine with in output levels of quality,
a step of training a machine learning model, said machine learning model receiving said database as training data, and
registering the trained machine learning model in the processing unit.

9. Process according to claim 8, wherein the values in said database are measured on distinct coating machines located in distinct countries, and said trained machine learning model is usable on coating machines located in at least two distinct countries.

10. Process according to claim 8, wherein:
said database is divided in a training set on the basis of which said machine learning model is trained and a test set on the basis of which said machine learning model is assessed,
to assess said machine learning model, the technical feature values recorded in the test set are used as input for the trained machine learning model and the obtained output are compared with the corresponding levels of quality recorded in the test set.

11. Process according to claim 10, wherein said machine learning model is assessed if a parameter quantifying the rate of false positives is greater than a predetermined threshold, a false positive corresponding to a situation where a low level of quality is not detected by the machine learning model.

12. Processing unit programmed for predicting a level of quality of a vacuum into a vacuum chamber of a coating machine suitable for coating optic elements said processing unit comprising an input interface for acquiring at least a value of at least one technical feature of the coating machine during a coating process of the optic elements (8), and a predicting unit for predicting said level of quality from the at least one acquired value by means of a machine learning model, said at least one technical feature value being an input of said machine learning model and said level of quality being an output of said machine learning model.

13. Processing unit according to claim 12, suitable for performing a process according to claim 1.

14. A vacuum coating machine suitable for coating optic elements comprising:
a vacuum chamber housing said optic elements,
a pumping device to evacuate any gas from said vacuum chamber,
acquiring means suitable to acquire at least a value of at least one technical feature of the coating machine during a coating process of said optic elements,
a processing unit according to claim 1.

15. The vacuum coating machine according to claim 14, comprising a reporting unit connected to said processing unit and suitable to communicate the predicted level to an individual, said reporting unit being preferably a loudspeaker generating an audible signal to communicate the predicted level of quality or a screen displaying a visual representation of the predicted level of quality.
